(19) United States
(12) Patent Application Publication
(10) Pub. No.: US 2016/0289124 A1
(43) Pub. Date: Oct. 6, 2016

(54) THERMAL CHEMICAL VAPOR DEPOSITION PRODUCT AND PROCESS OF USING A THERMAL CHEMICAL VAPOR DEPOSITION PRODUCT

(71) Applicant: SILCOTEK CORP., Bellefonte, PA (US)

(72) Inventors: James B. MATTZELA, Port Matilda, PA (US); Min YUAN, State College, PA (US); David A. SMITH, Bellefonte, PA (US); Paul H. SILVIS, Port Matilda, PA (US)

(21) Appl. No.: 14/675,806

(22) Filed: Apr. 1, 2015

(51) Int. Cl. C04B 35/622; C23C 16/44; C04B 35/14; C23C 16/50

(52) U.S. Cl. CPC C04B 35/62222; C23C 16/50; C23C 16/44; C04B 35/14

(57) ABSTRACT

Thermal chemical vapor deposition products and processes are disclosed. The products include a ceramic substrate and a non-porous surface on the ceramic substrate, the non-porous surface including a ceramic material. The process includes transporting fluid along a non-porous surface, the non-porous surface being positioned on a ceramic substrate and being a thermal chemical vapor deposition coating.

### FIELD OF THE INVENTION

The present invention is directed to thermal chemical vapor deposition processes and products produced from such processes. More particularly, the present invention is directed to such processes and products with non-porous surfaces.

### BACKGROUND OF THE INVENTION

Often, surfaces of substrates do not include desired performance characteristics. The failure to include specific desired performance characteristics can result in surface degradation in certain environments, an inability to meet certain performance requirements, or combinations thereof. For example, in certain environments, substrate surfaces can be subjected to wear and other undesirable surface activities such as chemical adsorption, catalytic activity, corrosive attack, oxidation, byproduct accumulation or stiction, and/or other undesirable surface activities.

Undesirable surface activities can cause chemisorption of other molecules, reversible and irreversible physisorption of other molecules, catalytic reactivity with other molecules, attack from foreign species, a molecular breakdown of the surface, physical loss of substrate, or combinations thereof. Specifically, ceramic substrates typically include porosity and surface reactivity that can contribute to reagent retention, carryover, and contamination.

A thermal chemical vapor deposition process and product that show one or more improvements in comparison to the prior art would be desirable in the art.

### BRIEF DESCRIPTION OF THE INVENTION

In an embodiment, a thermal chemical vapor deposition product includes a ceramic substrate and a non-porous surface on the ceramic substrate, the non-porous surface including a ceramic material.

In another embodiment, a thermal chemical vapor deposition product includes a ceramic substrate and a non-porous surface on the ceramic substrate. The non-porous surface is a thermal chemical vapor deposition coating, the thermal chemical vapor deposition coating including a silicon oxide. The ceramic substrate includes a porosity of at least 50%. The non-porous surface includes a porosity of less than 1%.

In another embodiment, a process includes transporting fluid along a non-porous surface, the non-porous surface being positioned on a ceramic substrate and being a thermal chemical vapor deposition coating.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 shows an embodiment of a thermal chemical vapor deposition product having a non-porous surface coating, according to the disclosure.

FIG. 2 shows a diffusion layer according to an embodiment of a thermal chemical vapor deposition product having a non-porous surface coating between a substrate and a coating, according to the disclosure.

Wherever possible, the same reference numbers will be used throughout the drawings to represent the same parts.

### DETAILED DESCRIPTION OF THE INVENTION

Provided are a thermal chemical vapor deposition process and product. Embodiments of the present disclosure, for example, in comparison to concepts failing to include one or more of the features disclosed herein, increase thermal insulation, decrease thermal conductivity, decrease coating porosity, permit use of ceramic coatings on ceramic substrates, permit use of ceramic substrates in vacuum processing, permit use of ceramic substrates in plasma processing, permit use of ceramic substrates in porosity-impacted processes, or a combination thereof.

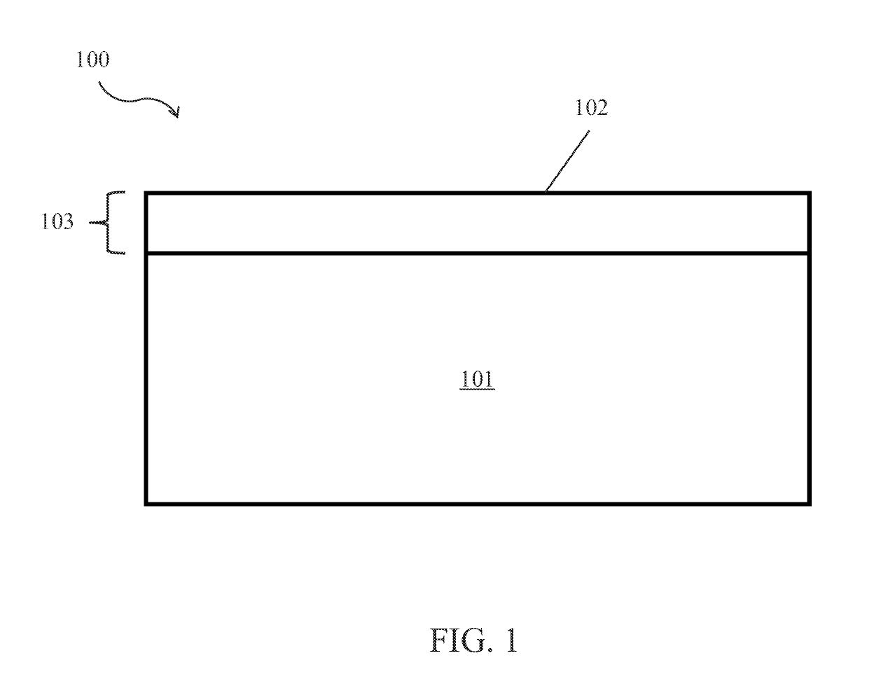

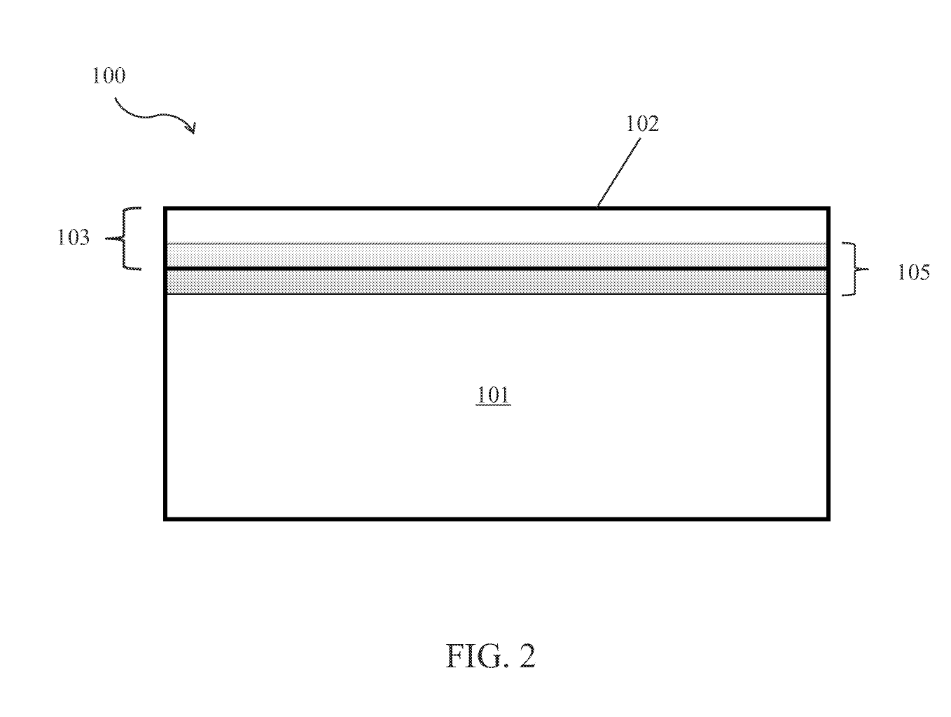

Referring to FIGS. 1 and 2, an article 100 includes a ceramic substrate 101 and a coating 103 positioned over the substrate 101. The coating 103 forms a non-porous surface 102 on the ceramic substrate 101. In one embodiment, in comparison to the ceramic substrate 101, the non-porous surface 102 has one or more of lower surface activity, lower reactivity, and lower adsorption.

As used herein, the term “non-porous” refers to having porosity of less than 30% (for example, 0%) and/or have pore width of less than 0.1 micrometers (for example, no pore width). In contrast to the non-porous surface 102, the ceramic substrate 101 includes any porous or substantially porous ceramic material, such as, but not limited to, oxides, nitrides, and/or carbides of aluminum, zirconium, silicon, tungsten, titanium, or a combination thereof.

Porosity of ceramic materials is capable of being measured by thermogravimetric volatilization of liquids and/or by mercury porosimetry. Based upon such measuring techniques, in general, values for porosity of ceramics are between 30% and 80% pore concentration and between 0.1 and 15 micrometer pore width.

Substantially porous ceramic materials have porosity of 55%, between 40% and 70%, between 50% and 60%, or any suitable combination, sub-combination, range, or sub-range therein and/or have pore width of between 1 micrometers and 14 micrometers, between 2 micrometers and 10 micrometers, between 5 micrometers and 14 micrometers, between 5 micrometers and 10 micrometers, or any suitable combination, sub-combination, range, or sub-range therein.

Porous ceramic materials have porosity of 80%, at least 70%, at least 60%, or any suitable combination, sub-combination, range, or sub-range therein and/or have pore width of 15 micrometers, at least 5 micrometers, at least 10 micrometers, at least 14 micrometers, or any suitable combination, sub-combination, range, or sub-range therein.

In one embodiment, the coating 103 is formed from decomposition of a silane material, such as, but not limited to, dimethylsilane, trimethylsilane, or a combination thereof. As disclosed in U.S. patent application Ser. No. 13/876,328, and U.S. patent application Ser. No. 13/504,533, both of which are incorporated herein by reference in their entirety, a process for forming the coating 103 includes chemical vapor deposition (CVD) of dimethylsilane. The thermal chemical vapor deposition is by thermal application and not plasma-assisted methods.

In one embodiment, forming the coating 103 over the substrate 101 through the CVD includes thermally decomposing dimethylsilane and/or any other suitable thermal decomposition gas and depositing amorphous carbosilane. In general, suitable species of the decomposition gas include, but are not limited to, an organosilane, dimethylsilane, any silane gas, or any other suitable chemical vapor decomposition gas. Other suitable materials for the introducing and/or subsequent treatment include, but are not limited to, trimethylsilane, dialkylsilyl dihydride, alkylsilyl trihydride, dialkylsilyl dihydride, alkylsilyl trihydride, organofluorotrialkoxysilanes, and/or organofluorosilylhydrides.

Any portion of the chemical vapor deposition process is capable of being preceded or followed by selectively applying a purge gas to the chemical vapor deposition chamber. The purge gas is nitrogen, helium, argon, or any other suitable inert gas. The purging is in one purge cycle, two purge cycles, three purge cycles, more than three purge cycles, or any suitable number of purge cycles that permits chemical vapor deposition chamber to be a chemically inert environment. The purging to provide a chemically inert environment is capable of eliminating or substantially eliminating exposure of the ceramic substrate 101 to a corrosive environment, which facilitates the forming of the coating 103.

In one embodiment, prior to forming the coating 103, the ceramic substrate 101 is modified for CVD processing. Modifying the ceramic substrate 101 includes any suitable treatment method. For example, modifying the ceramic substrate 101 is capable of being achieved by isolating the ceramic substrate 101 in a chemical vapor deposition chamber, preheating the ceramic substrate 101, flushing the chamber with an inert gas, and evacuating the chamber. The modifying of the ceramic substrate 101 is capable of increasing adherence of the coating 103 to the ceramic substrate 101, which increases wear resistance of the article 100. In addition, modifying the ceramic substrate 101 through desorbing water is capable of reducing or eliminating corrosion and/or fouling of the article 100.

In one embodiment, isolating of the ceramic substrate 101 is performed in an inert atmosphere within the chamber. The flow of gas and/or maintenance of a vacuum in the chamber provides the controlled atmosphere. A heat source controls the temperature in the chamber to desorb water and remove remaining contaminants from the ceramic substrate 101. For example, in a further embodiment, the ceramic substrate 101 to be treated is included within a chemical vapor deposition chamber with tubing connections to allow gas flow in and out of the chemical vapor deposition chamber. The chamber includes multiple controlled inlets and outlets configured for providing and removing multiple gas streams and/or a vacuum to one or more outlet tubes.

Depending upon the cleanliness of the ceramic substrate 101, in one embodiment, the ceramic substrate 101 is prepared by heating at a temperature above 100° C. and a pressure of below 1 atmosphere for a period ranging from a few minutes to 15 hours. Generally, the temperature of the heating corresponds to the properties of the ceramic substrate 101. The period is from 0.5 to 15 hours and the heating, for example, is at about 450° C. for about 2 hours. After preparation under vacuum, in a further embodiment, the chamber is selectively flushed with an inert gas and evacuated.

The thermal decomposition of the decomposition gas includes introducing the decomposition gas into a reaction chamber at a pressure and temperature sufficient to decompose the decomposition gas, depositing constituents from the decomposition onto the ceramic substrate 101, coating the ceramic substrate 101 for a period of time to achieve a thickness, and/or purging the chamber of decomposition gas. For example, in one embodiment, the dimethylsilane is introduced into the reaction chamber under reduced pressure or with an inert gas, such as nitrogen, helium, and/or argon, as a partial pressure dilutant. After introduction into the reaction chamber, the dimethylsilane is thermally dissociated into molecular fragments including H, C, Si, and combinations thereof. The thermally dissociated constituents are then deposited onto the ceramic substrate 101, thereby forming the coating 103 with a material including silicon, carbon, and hydrogen resulting from decomposition of dimethylsilane.

In one embodiment, at least during the introducing of the decomposition gas, the operating the chemical vapor deposition chamber is substantially devoid of catalyst (for example, being below a level that impacts the process) or devoid of catalyst (for example, being absent at detectable levels and/or being completely absent).

Although not intending to be bound by theory, it is believed that the dimethylsilane thermally decomposes to form carbosilyl fragments, which recombine and bind to the substrate 101. It is believed that the resultant coating includes amorphous carbosilanes having carbon, silicon, and hydrogen on the substrate surface as well as on exposed surfaces of the chamber. The composition of the coating 103 includes a 1:0.95:0.12 ratio of C:Si:O (the small presence of oxygen from a depth of 5 nanometers to 120 nanometers is likely attributed to background noise and trace contamination). In contrast, the composition of dimethylsilane introduced into the chemical vapor deposition chamber has about a 2:1 ratio of C:Si. It is believed that CHₓ (x=0−3) moieties are retained and Si—C bonds are broken thus indicating that the coating 103 includes an amorphous array of Si—C bonding and/or a polycrystalline microstructure. The amorphous array provides additional benefits such as decreased cracking or flaking (for example, upon tensile or compressive forces acting on the substrate 100) and/or increased adhesion.

Depending upon the decomposition gas and other parameters, a suitable pressure for the decomposition is between 1.0 pound per square inch absolute (psia) and 250 psia, between 1.0 and 200 psia, between 1.0 psia and 150 psia, between 1.0 psia and 100 psia, between 1.0 psia and 75 psia, between 1.0 psia and 50 psia, between 1.0 psia and 40 psia, between 1.0 psia and 30 psia, between 1.0 psia and 20 psia, between 1.0 psia and 10 psia, between 1.0 psia and 5.0 psia, between 5 psia and 40 psia, 1.0 psia, 5 psia, 40 psia, 100 psia, 200 psia, or any suitable combination, sub-combination, range, or sub-range therein.

Depending upon the decomposition gas and other parameters, a suitable temperature for the decomposition is less than 30° C., less than 60 ° C., less than 100° C., less than 150° C., less than 200° C., less than 250° C., less than 300 ° C., less than 350° C., less than 400° C., less than 440° C., less than 450° C., less than 500° C., less than 600° C., between 100° C. and 300° C., between 125° C. and 275° C., between 200° C. and 300° C., between 230° C. and 270° C., between 300° C. and 600° C., between 400° C. and 500° C., or any suitable combination, sub-combination, range, or sub-range therein.

Depending upon the decomposition gas and other parameters, a suitable period of time for the decomposition are between 10 minutes and 24 hours, between 1 hours and 10 hours, between 2 hours and 10 hours, between 4 hours and 6 hours, between 4 hours and 8 hours, at least 10 minutes, at least 1 hours, at least 4 hours, at least 10 hours, less than 10 hours, less than 8 hours, less than 6 hours, less than 4 hours, or any suitable combination, sub-combination, range, or sub-range therein.

For example, in one embodiment, the dimethylsilane gas is introduced into the reaction chamber at a pressure of between 1.0 psia and 200 psia, and a temperature of between 300° C. and 600° C., and exposed to the ceramic substrate 101 for 30 minutes to 24 hours. In another embodiment, the dimethylsilane gas is introduced into the reaction chamber at a pressure of between 5 psia and 40 psia, and a temperature between 400° C. and 500° C., and exposed to the ceramic substrate 101 for 15 hours.

In one embodiment, the non-porous surface 102 provided by the coating 103 is devoid or substantially devoid of surface activity, which decreases or eliminates reagent retention, carryover, contamination, and/or build-up on the non-porous surface 102, as compared to the ceramic substrate 101 without the coating 103. In addition to reagent reactivity, surface activity refers to, but is not limited to, discoloration of the non-porous surface 102 and/or the substrate 101, for example, to produce a colorless-to-brown appearance. Furthermore, reducing or eliminating the surface activity of the article 100 increases the resistance of the article 100 to corrosion and/or fouling. In corrosive wear the surface reacts with the environment and reaction products are formed on the surface asperities. Attrition of the reaction products then occurs as a result of crack formation, and/or abrasion, in the contact interactions of the materials.

In another embodiment, a fluid is transported along the non-porous surface 102 of the ceramic substrate 101. The non-porous surface 102 decreases or eliminates reagent retention, reagent carryover, and or reagent contamination from the fluid, as compared to uncoated ceramic substrates 101 and/or oxide layers formed directly on the ceramic substrates 101.

In one embodiment, the coating 103 is formed by cold fill deposition. Cold fill deposition includes positioning the ceramic substrate 101 in a chemical vapor deposition chamber, then operating the chemical vapor deposition chamber. The operating of the chemical vapor deposition chamber includes purging the chemical vapor deposition chamber, introducing a decomposition gas to the chemical vapor deposition chamber, heating the chemical vapor deposition chamber, or a combination thereof. Throughout the operating of the chemical vapor deposition chamber, the pressure is adjusted or within a range, for example, of between 0.01 psia and 200 psia, between 1.0 psia and 100 psia, between 5 psia and 40 psia, about 1.0 psia, about 5 psia, about 40 psia, about 100 psia, about 200 psia, or any suitable combination, sub-combination, range, or sub-range therein.

The cold fill deposition includes introduction of the decomposition gas at a sub-decomposition temperature that is below the thermal decomposition temperature of the decomposition gas. As used herein, the phrase “sub-decomposition temperature” refers to conditions at which the decomposition gas will not thermally decompose. Depending upon the species of the decomposition gas, suitable sub-decomposition temperatures include, but are not limited to, less than 30° C., less than 60° C., less than 100° C., less than 150° C., less than 200° C., less than 250° C., less than 300° C., less than 350° C., less than 400° C., less than 440 ° C., less than 450° C., between 100° C. and 300° C., between 125° C. and 275° C., between 200° C. and 300° C., between 230° C. and 270° C., or any suitable combination, sub-combination, range, or sub-range therein.

During and/or after the introducing of the decomposition gas, the operating of the chemical vapor deposition chamber includes heating the chemical vapor deposition chamber to a super-decomposition temperature that is equal to or above the thermal decomposition temperature of the decomposition gas. As used herein, the phrase “super-decomposition temperature” refers to conditions at which the decomposition gas will thermally decompose. Heating the chemical vapor deposition chamber to the super-decomposition temperature in the presence of the decomposition gas forms the coating 103 on at least a surface of the ceramic substrate 101, which forms the non-porous surface 102.

The heating of the chemical vapor deposition chamber is at any suitable heating rate from the sub-decomposition temperature to the super-decomposition temperature. Depending upon the species of the decomposition gas, suitable super-decomposition temperatures include, but are not limited to, between 440° C. and 460° C., greater than 460° C., greater than 450° C., greater than 460° C., greater than 480° C., greater than 500° C., or any suitable combination, sub-combination, range, or sub-range therein. Suitable heating rates include, but are not limited to, between 6° C. per minute and 10° C. per minute, between 7° C. per minute and 9° C. per minute, greater than 6° C. per minute, greater than 7° C. per minute, less than 10° C. per minute, less than 9° C. per minute, at 8° C. per minute, or any suitable combination, sub-combination, range, or sub-range therein. At such rates, in one embodiment, the heating of the chemical vapor deposition chamber is for a period of between 3 minutes and 10 minutes, a period of between 5 minutes and 10 minutes, a period of between 7 minutes and 10 minutes, a period of between 3 minutes and 7 minutes, a period of between 3 minutes and 5 minutes, or any suitable combination, sub-combination, range, or sub-range therein.

The cold fill CVD process disclosed herein is capable of providing chemical vapor deposition of the decomposition gas to form the coating 103 on an increased number of substrates. Furthermore, in addition to the advantages disclosed for the coating 103 formed through CVD, the coating 103 formed through cold fill deposition, as disclosed above, is capable of increasing cross-link density of the coating 103.

In one embodiment, as illustrated in FIG. 2, the deposited material diffuses into the ceramic substrate 101, forming a diffusion zone 105 extending between the ceramic substrate 101 and the coating 103. Subsequent to forming the coating 103, the chamber is capable of being purged of dimethylsilane and volatile, non-deposited carbosilyl fragments. If a thicker deposition layer is desired, deposition conditions are changed. This is accomplished by changing temperature, pressure, time, or combinations thereof. Multiple layers are also capable of being applied by repeating the introduction and thermal decomposition of the dimethylsilane. Together, the one or more layers of the coating 103 form the non-porous surface 102 on the ceramic substrate 101.

While a thickness of the coating 103 depends on the geometry of the substrate 101 to be coated and the type of finish required, in an embodiment made according to the methods disclosed herein, the coating 103 has a thickness of between 100 nm and 10,000 nm, between 100 nm and 5,000 nm, between 200 nm and 5,000 nm, between 100 nm and 3,000 nm, between 300 nm and 1,500 nm, or any combination, sub-combination, range, or sub-range thereof. In another embodiment, the diffusion zone 105 is between 5 nm and 500 nm. For example, in a further embodiment, the coating 103 extends to 130 nm and includes a portion of the diffusion zone 105, which extends 20 nm, and is identifiable based upon an increased concentration of O and decreased in concentration of C and Si (for example, by at least a factor of four).

In one embodiment, the CVD of the dimethylsilane is followed by oxidation to form a carboxysilane and/or silicon oxide. The carboxysilane and/or silicon oxide is non-porous or substantially non-porous, providing a non-porous or substantially non-porous, non-conductive, and/or thermally insulating coating. In contrast to the belief that ceramic coatings are not suitable for ceramic substrates due to a porosity of ceramic coatings, the CVD processes disclosed herein form the non-porous surface 102 from a ceramic material. Doing so permits embodiments with the ceramic substrates 101 being in applications, such as, but not limited to, vacuum processing, plasma processing, semiconductor process equipment, and/or any other porosity-impacted process. Furthermore, such embodiments are more uniform/homogenous in composition and/or more uniform/homogenous structure (such as, for example, thickness, phase, and/or grain size) as compared to the ceramic substrate 101 and/or oxide layers formed directly on the ceramic substrate 101. As compared to non-diffusion coatings, embodiments of the non-porous surface 102 formed through CVD of the coating 103 also provide increased chemical resistance, increased inertness, and increased adhesion of the coating 103 to the ceramic substrate 101.

Oxidation of the coating 103 includes exposure to any suitable chemical species capable of donating a reactive oxygen species into the coating 103 under predetermined oxidation conditions. In general, oxidation is a bulk reaction that affects the bulk of the coating 103. The oxidation increases hardness and/or wear resistance of carbosilane and functionalized carbosilane-based chemical vapor deposition process materials of the non-porous surface 102. The oxidation is capable of being controlled by increasing or decreasing the temperature within the chamber, the exposure time within the chamber, the type and/or amount of diluent gases, pressure, and/or other suitable process conditions. Control of the oxidation is capable of increasing or decreasing the amount and/or depth of oxidation and, thus, the wear resistance and/or hardness of the non-porous surface 102. By increasing the wear resistance, the oxidation of the non-porous surface 102 increases resistance of the article 100 to erosion (from both solid and liquid), which occurs when impinging particles or stream contact the surface of the article 100.

The chemical species for the oxidation of the coating 103 are selected based upon the desired properties of the non-porous surface 102. Suitable chemical species for the oxidation of the coating 103 include, for example, water, oxygen, air, nitrous oxide, ozone, peroxide, and combinations thereof. In one embodiment, the coating 103 is oxidized with water as an oxidizing agent (for example, within a temperature range of 100° C. to 600° C., a temperature range of 300° C. to 600° C., or at a temperature of 450° C.). In this embodiment, the oxidizing lowers friction of the non-porous surface 102 (in comparison to using an oxidizing reagent of air and water), decreases wear resistance of the non-porous surface 102 (for example, in comparison to using an oxidizing reagent of air and water), and forms Si—O—Si groups. The Si—O—Si groups formed in this embodiment are capable of further decreasing or eliminating surface activity of the non-porous surface 102 as compared to an uncoated ceramic substrate 101.

In another embodiment, the coating 103 is oxidized with an oxidizing reagent including air and water (for example, within a temperature range of 100° C. to 600° C., a temperature range of 300° C. to 600° C., or at a temperature of 450° C.). In this embodiment, the oxidizing over-oxidizes and decreases an amount of C—H groups (for example, in comparison to using water alone as an oxidizing reagent), decreases an amount of Si-C groups (for example, in comparison to using water alone as an oxidizing reagent), and increases an amount of Si—OH/C—OH groups (for example, in comparison to using water alone as an oxidizing reagent). Depending on the reagents contacting the non-porous surface 102, the decreased amount of C—H and Si—C groups, and/or the increased an amount of Si—OH/C—OH groups are capable of further decreasing or eliminating surface activity of the non-porous surface 102.

In an alternate embodiment, the coating 103 is oxidized with air (only) (for example, within a temperature range of 100° C. to 600° C., a temperature range of 300° C. to 600° C., or at a temperature of 450° C.). In this embodiment, the oxidizing lowers friction of the non-porous surface 102, increases wear resistance of the non-porous surface 102 (for example, in comparison to using an oxidizing reagent of water), and forms Si—O—Si and Si—OH groups. The Si—O—Si and Si—OH groups are capable of further decreasing or eliminating surface activity of the non-porous surface 102.

In one embodiment, the coating 103 is oxidized with nitrous oxide (N₂O). Specifically, N₂O is applied under heat (for example, about 450° C.) with a pressure of substantially pure N₂O in a vessel with carbosilane-coated samples. In this embodiment, the oxidizing over-oxidizes and the over-oxidizing increases an amount of N—H, Si—OH, and/or C—OH groups, and results in having relatively fragile scratch resistance. Alternatively, the oxidizing is performed with ozone. In this embodiment, the oxidizing is believed to decrease wear resistance, decrease chemical resistance, decrease scratch resistance, decrease hardness, and increase acid resistance/corrosion resistance of the non-porous surface 102.

Any other suitable treating steps are performed on the coating 103 after the decomposition gas is introduced, to form the non-porous surface 102. The treating of the coating 103 includes, for example, heating and/or modifying the coating 103 applied over the substrate 101. In one embodiment, the treating includes exposure of the substrate 101 and/or the coating 103 to a suitable organosilane reagent. One suitable organosilane reagent is a trifunctional organosilane that consists of the general formula RR′R″Si-H, where R, R′, R″ are organofunctional groups. Examples of the organofunctional groups are alkyl, aryl, halogenated alkyl and aryl, ketones, aldehydes, acyl, alcohol, epoxy, and nitro—organo groups, and organometallic functionalities. In one embodiment, the organosilane is trimethylsilane.

By modifying and varying the R′ groups, or by using other molecules capable of hydroxyl reactivity, surface properties of the treated non-porous surface 102 (for example, the air-oxidized carboxysilane layer) are adjusted. For example, in one embodiment, the adjustments increase or decrease hardness and wear resistance, inertness, stiction, coking, electrochemical impedance, contact angle, and combinations thereof. The adjustments provided through varying the R′ groups provide physical performance characteristics expanding the applicability of ceramic substrates 101 in the semiconductor industry. The R-groups are capable of being formed by hydrocarbons, substituted hydrocarbons, carbonyls, carboxyls, esters, ethers, amines, amides, sulfonic acids, organometallic complexes, and/or epoxides. Although not intending to be bound by theory, it is believed that the moieties of silicon hydride thermally react, via a hydrosilyation mechanism, with unsaturated hydrocarbon groups to covalently bond to the non-porous surface 102 of the ceramic substrate 101. In one embodiment, the non-porous surface 102 on all exposed surface within the reaction chamber includes covalently-bound R-groups which include the R-group and carbon, silicon, and hydrogen moieties.

In one embodiment, after forming the coating 103 on the ceramic substrate 101, the coating 103 is treated by trimethylsilane. In another embodiment, the coating 103 is oxidized to form the carboxysilane prior to treatment by trimethylsilane. In a further embodiment, after treating the carboxysilane with trimethylsilane, the coating 103 is functionalized. Treatment with the trimethylsilane is capable of providing increasing (over untreated oxidized and/or functionalized coatings) in inertness, corrosion resistance, hydrophobicity, pH resistance, wear resistance and hardness, and combinations thereof. Additionally or alternatively, the coating 103 is capable of being adjusted for anti-stiction and anti-coking properties, which reduces or eliminates byproduct accumulation and/or reagent adherence/retention on the non-porous surface 102, as compared to untreated coatings and/or substrates.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A thermal chemical vapor deposition product, comprising:
a ceramic substrate; and
a non-porous surface on the ceramic substrate, the non-porous surface including a ceramic material.

2. The thermal chemical vapor deposition product of claim 1, wherein the non-porous surface is formed from thermal chemical vapor deposition of dimethylsilane.

3. The thermal chemical vapor deposition product of claim 2, wherein the ceramic material comprises silicon oxide.

4. The thermal chemical vapor deposition product of claim 2, wherein the non-porous surface is oxidized.

5. The thermal chemical vapor deposition product of claim 4, wherein the non-porous surface is functionalized.

6. The thermal chemical vapor deposition product of claim 2, wherein the non-porous surface is treated with trimethylsilane.

7. The thermal chemical vapor deposition product of claim 6, wherein the trimethylsilane is functionalized.

8. The thermal chemical vapor deposition product of claim 1, wherein the ceramic substrate has porosity of greater than 50%.

9. The thermal chemical vapor deposition product of claim 1, wherein the ceramic substrate has porosity of greater than 70%.

10. The thermal chemical vapor deposition product of claim 1, wherein, in comparison to the ceramic substrate, the non-porous surface has one or more of lower surface activity, lower reactivity, and lower adsorption.

11. The thermal chemical vapor deposition product of claim 1, wherein the non-porous surface includes a porosity of less than 1%.

12. The thermal chemical vapor deposition product of claim 1, wherein the non-porous surface is deposited at a super-decomposition temperature of dimethylsilane.

13. The thermal chemical vapor deposition product of claim 1, wherein the non-porous surface is substantially devoid of surface activity.

14. The thermal chemical vapor deposition product of claim 1, wherein the non-porous surface is substantially devoid of discoloration.

15. A thermal chemical vapor deposition product, comprising:
a ceramic substrate; and
a non-porous surface on the ceramic substrate;
wherein the non-porous surface is a thermal chemical vapor deposition coating, the thermal chemical vapor deposition coating including a silicon oxide;
wherein the ceramic substrate includes a porosity of at least 50%; and
wherein the non-porous surface includes a porosity of less than 1%.

16. The thermal chemical vapor deposition product of claim 15, wherein the non-porous surface is non-conductive.

17. The thermal chemical vapor deposition product of claim 15, wherein the non-porous surface comprises a thermal insulator.

18. A process comprising transporting fluid along a non-porous surface, the non-porous surface being positioned on a ceramic substrate and being a thermal chemical vapor deposition coating.

19. The process of claim 18, wherein the process is a porosity-impacted process.

20. The process of claim 19, wherein the porosity-impacted process is selected from the group consisting of vacuum processing, plasma processing, and a combination thereof.
